(19) United States
(12) Patent Application Publication
(10) Pub. No.: US 2024/0322607 A1
(43) Pub. Date: Sep. 26, 2024

(54) POWER RECEIVER ELECTRONICS

(71) Applicant: LASERMOTIVE, INC., Kent, WA (US)

(72) Inventors: Thomas J. NUGENT, Jr., Bellevue, WA (US); Thomas J. SAYLES, Fall City, WA (US); David J. BASHFORD, Kent, WA (US); Thomas BASHFORD, Issaquah, WA (US); Drew C. ELDEEN, Maple Valley, WA (US)

(21) Appl. No.: 18/262,513

(22) PCT Filed: Jan. 24, 2022
(86) PCT No.: PCT/US22/13570

§ 371 Date: Jul. 21, 2023

Related U.S. Application Data
(60) Provisional application No. 63/140,256, filed on Jan. 22, 2021.
(60) Provisional application No. 63/286,516, filed on Dec. 6, 2021.

(51) Int. Cl. H02J 50/30; H01L 31/0232; H01L 31/0475; H01L 31/05; H02S 40/42

(52) U.S. Cl. CPC H02J 50/30; H01L 31/0475; H01L 31/0504; H01L 31/02327; H02S 40/42

(57) ABSTRACT

A free-space power receiver includes layouts of photovoltaic cells selected to optimize power extraction even when a power beam moves or changes profile on the receiver. The receiver may also include a circuit board having apertures therein whereby light may reach the photovoltaic cells. The circuit board may include suitable wiring for connecting the photovoltaic cells to one another and to a load for extraction of power.

### CROSS-REFERENCE TO RELATED APPLICATIONS

This application claims benefit under 35 U.S.C. § 119(e) of U.S. Provisional Patent Application No. 63/140,256, filed Jan. 22, 2021, and to U.S. Provisional Patent Application No. 63/286,516, filed Dec. 6, 2021, each of which is incorporated herein by reference to the extent not inconsistent herewith.

### BACKGROUND

Power beaming is an emerging method of transmitting power to places where it is difficult or inconvenient to access using wires, by transmitting a beam of electromagnetic energy to a specially designed receiver which converts it to electricity. Power beaming systems may be free-space power (FSP), where a beam is sent through atmosphere, vacuum, liquid, or other non-optically-designed media, or power-over-fiber (PoF), where the power is transmitted through an optical fiber. The latter may share certain disadvantages with wires in some circumstances, but may also offer increased transmission efficiency, electrical isolation, safety, and/or reduced mass. FSP may be more flexible, but it may also offer more challenges for accurate targeting of receivers and avoiding hazards such as reflections and objects intruding on the power beam.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventors' approach to the particular problem, which in and of itself may also be inventive.

### SUMMARY

In one aspect, a power receiver includes a plurality of photovoltaic (PV) cells, each PV cell having an active surface configured to receive light for conversion to electric power, and a cathode connector and an anode connector configured to produce a voltage therebetween when the active surface of the PV cell is exposed to light. The receiver further includes a circuit board connected to at least one of the cathode and anode connectors, the circuit board having a plurality of apertures therein, and an output connector configured to electrically connect the circuit board to a load. Each PV cell is positioned to receive light that has passed through at least one of the plurality of apertures in the circuit board.

In another aspect, a power receiver includes a plurality of photovoltaic (PV) cells disposed on a support surface, the PV cells divided into a plurality of voltage groups, each voltage group having a selected output voltage and output current, and electrical wiring for interconnecting the PV cells. The wiring is configured to connect each PV cell within a voltage group in parallel and to connect each voltage group to at least one other voltage group in series. The PV cells of each voltage group are arranged to be noncontiguous with one another on the support surface, and the plurality of voltage groups exhibits a current mismatch of less than 5%, where current mismatch is defined as the difference between the greatest output current and the least output current, divided by the average output current, when the receiver is exposed to a power beam.

In another aspect, a power receiver includes a plurality of photovoltaic (PV) cells disposed on a support surface to form a PV array, the PV cells divided into a plurality of voltage groups, each voltage group having a selected output voltage and output current, and electrical wiring for interconnecting the PV cells. The wiring is configured to connect each PV cell within a voltage group in parallel and to connect each voltage group to at least one other voltage group in series. The PV cells of each voltage group are arranged in a repeating pattern along a first axis of the PV array, and where the repeating pattern is staggered along a second axis of the PV array by an offset value, the offset value selected so that PV cells in the same voltage group are not adjacent to one another.

In another aspect, a power receiver includes a plurality of photovoltaic (PV) cells disposed on a support surface to form a PV array, the PV cells divided into a plurality of voltage groups, each voltage group having a selected output voltage and output current, and electrical wiring for interconnecting the PV cells. The wiring is configured to connect each PV cell within a voltage group in parallel and to connect each voltage group to at least one other voltage group in series. Each voltage group has the property that a Voronoi diagram of positions of PV cells in the voltage group has a median Voronoi cell aspect ratio of less than 1.4.

In another aspect, a power receiver includes a plurality of photovoltaic (PV) cells, a circuit board having a plurality of apertures therein, and an output connector. Each PV cell has an active surface configured to receive light for conversion to electric power, and a cathode connector and an anode connector configured to produce a voltage there between when the active surface of the PV cell is exposed to light. The circuit board is connected to at least one of the cathode and anode connectors, and the output connector is configured to electrically connect the circuit board to a load. Each PV cell of the plurality is positioned to receive light that has passed through at least one of the plurality of apertures in the circuit board.

In another aspect, a power receiver includes a heat sink including a first side, a second side, and an opening passing from the first side to the second side, a power collection device in thermal contact with the first side of the heat sink, an electronic component disposed on the second side of the heat sink, and an electrical connector arranged within the opening in the heat sink. The electrical connector connects the power collection device to the electronic component.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF FIGURES

The drawing figures depicts one or more implementations in according with the present teachings, by way of example only, not by way of limitation. In the figures, like reference numerals refer to the same or similar elements. Furthermore, it should be understood that the drawings are not necessarily to scale.

FIG. 1 is a schematic diagram of a power beaming transmitter and receiver.

FIG. 2 is an abstracted diagram of the power beaming transmitter of FIG. 1, showing interrelationships between components of the transmitter.

FIG. 3 is an abstracted diagram of the power receiver of FIG. 1, showing interrelationships between components of the receiver.

FIG. 4(a) is a schematic diagram of a power receiver geometry including a circuit board having apertures therein.

FIG. 4(b) shows the power receiver of FIG. 4(a) from the side.

FIG. 5 is a schematic diagram of a power receiver geometry in combination with concentrators.

FIG. 6 is a diagram of a power receiver with a perforated heat sink.

FIG. 7a and FIG. 7b, referred to collectively herein as FIG. 7, are diagrams showing a top view and a bottom view of another power receiver implementation including a perforated vapor chamber.

FIG. 8 is a wiring scheme for a PV array.

FIG. 9(a) shows the PV cell layout of FIG. 3 of Kare.

FIG. 9(b) shows the PV cell layout of FIG. 5 of Kare, “doubled” by placing two copies of Kare's depicted array side-by-side.

FIG. 10 shows a Voronoi mesh for one voltage level for the array of FIG. 9(b), and a histogram of aspect ratios of the illustrated mesh.

FIG. 11 shows a PV array of approximately the same size and shape as FIG. 9(b) with a model beam profile.

FIG. 12 shows a Voronoi mesh for one voltage level for the array of FIG. 11, and a histogram of aspect ratios of the illustrated mesh.

FIG. 13 shows a Voronoi mesh corresponding to the mesh shown in FIG. 10, but with an expanded number of cells.

FIG. 14 shows a Voronoi mesh corresponding to the mesh shown in FIG. 12, but with an expanded number of cells.

FIG. 15 shows a square PV array layout showing voltage levels for each cell, with a beam profile superimposed.

FIG. 16 shows a Voronoi mesh for cells at one voltage level for the array of FIG. 15, and a histogram of aspect ratios of the illustrated mesh.

FIG. 17 shows a PV array layout having a roughly octagonal shape.

FIG. 18 shows a model beam profile for application to the array of FIG. 9(a).

FIG. 19 shows modeled level currents for the array shown in FIG. 9(a).

FIG. 20 shows a model beam profile for application to the array of FIG. 9(b).

FIG. 21 shows modeled level currents for the array shown in FIG. 9(b).

FIG. 22 shows modeled level currents for the array shown in FIG. 11.

FIG. 23 shows modeled level currents for the array shown in FIG. 14.

FIG. 24 shows modeled level currents for the array shown in FIG. 17.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high level, without detail, in order to avoid unnecessarily obscuring aspects of the present teachings. Those of ordinary skill in the art will nevertheless understand the features of these methods, procedures, components, and/or circuitry and how they may be used in the descriptions below. Other relevant material may be found in other patents and applications as follows:

| | | |
|---|---|---|
| U.S. Pat. No. 9,800,091 | Issued Oct. 24, 2017 | Aerial Platform Powered Via an |
| | | Optical Transmission Element |
| U.S. Pat. No. 10,374,466 | Issued Aug. 6, 2019 | Energy Efficient Vehicle with |
| | | Integrated Power Beaming |
| U.S. Pat. No. 10,459,114 | Issued Oct. 29, 2019 | Wireless Power Transmitter and |
| | | Receiver |
| U.S. Pat. No. 10,488,549 | Issued Nov. 26, 2019 | Locating Power Receivers |
| U.S. Pat. No. 10,580,921 | Issued Mar. 3, 2020 | Power-Over-Fiber Safety System |
| U.S. Pat. No. 10,634,813 | Issued Apr. 28, 2020 | Multi-Layered Safety System |
| U.S. Pat. No. 10,673,375 | Issued Jun. 2, 2020 | Power-Over-Fiber Receiver |
| U.S. Pat. No. 10,816,694 | Issued Oct. 27, 2020 | Light Curtain Safety System |
| U.S. Pat. No. 10,825,944 | Issued Nov. 3, 2020 | Device for Converting Electromagnetic |
| | | Radiation into Electricity, and Related |
| | | Systems and Methods |
| U.S. Pat. No. 11,105,954 | Issued Aug. 31, 2021 | Diffusion Safety System |
| U.S. application No. | Filed Aug. 22, 2018 | Remote Power Safety System |
| 16/079,073 | | |
| U.S. application No. | Filed Nov. 2, 2020 | Dual-Use Power Beaming System |
| 17/087,198 | | |
| U.S. application No. | Filed Nov. 19, 2021 | Remote Power Beam-Splitting |
| 17/613,015 | | |
| U.S. application No. | Filed Nov. 19, 2021 | Safe Power Beam Startup |
| 17/613,021 | | |
| U.S. application No. | Filed Nov. 19, 2021 | Beam Profile Monitor |
| 17/613,028 | | |
| U.S. Provisional Application | Filed Jan. 22, 2021 | Power Receiver Electronics |
| No. 63/140,256 | | |
| U.S. Provisional Application | Filed Jan. 22, 2021 | Light Curtain System with Enhanced |
| No. 63/140,236 | | Geometric Configurations |
| U.S. Provisional Application | Filed Nov. 13, 2021 | Beam Homogenization at Receiver |
| No. 63/279,087 | | |
| U.S. Provisional Application | Filed Nov. 19, 2021 | Beam Reshaping at Receiver |
| No. 63/281,618 | | |
| U.S. Provisional Application | Filed Dec. 6, 2021 | Perforated Heat Sink |
| No. 63/286,516 | | |
| International Application | Filed May 18, 2016 | Power Beaming VCSEL Arrangement |
| No. PCT/US16/33117 | | |
| International Application | Filed Sep. 16, 2020 | Optical Power for Electronic Switches |
| No. PCT/US20/51101 | | |

Each of these related applications and patents is incorporated by reference herein to the extent not inconsistent herewith.

As discussed above, power beaming is becoming a viable method of powering objects in situations where it is inconvenient or difficult to run wires. For example, free-space power beaming may be used to deliver electric power via a ground-based power transmitter to power a remote sensor, to recharge a battery, or to power an unmanned aerial vehicle (UAV) such as a drone copter, allowing the latter to stay in flight for extended periods of time. Power over fiber (PoF) systems usually require optical fiber (or an equivalent) to be run from a power source to a receiver, but may nevertheless provide electrical isolation and/or other advantages over traditional copper wires which carry electricity instead of light.

It will be understood that the term “light source” is intended to encompass all forms of electromagnetic radiation that may be used to transmit energy, and not only visible light. For example, a light source (e.g., a diode laser, fiber laser, light-emitting diode, magnetron, or klystron) may emit ultraviolet, visible, infrared, millimeter wave, microwave, radio waves, and/or other electromagnetic waves, any of which may be referred to herein generally as “light.” The term “power beam” is used herein interchangeably with “light beam” to mean a high-irradiance transmission, generally directional in nature, which may be coherent or incoherent, of a single wavelength or multiple wavelengths, and pulsed or continuous. A power beam may be free-space, PoF, or may include components of each. For example, a transmitter may transmit a free-space power beam to a receiver surface, which may conduct it as light over an optical fiber to a photovoltaic (PV) cell which converts it to electricity. For the sake of readability, the description may use the term “laser” to describe a light source; nevertheless, other sources such as (but not limited to) light-emitting diodes, magnetrons, or klystrons may also be contemplated unless context dictates otherwise.

For many applications, a power receiver is arranged to receive the free-space or PoF power beam and convert it to electricity, for example using PV cells or other components for converting light to electricity (e.g., a rectenna for converting microwave power or a heat engine for converting heat generated by the light beam to electricity). For the sake of readability, this application may refer to “PV cells” with the understanding that other components having a similar function (such as but not limited to those listed above) may be substituted without departing from the scope of the application.

### Power Beaming Systems

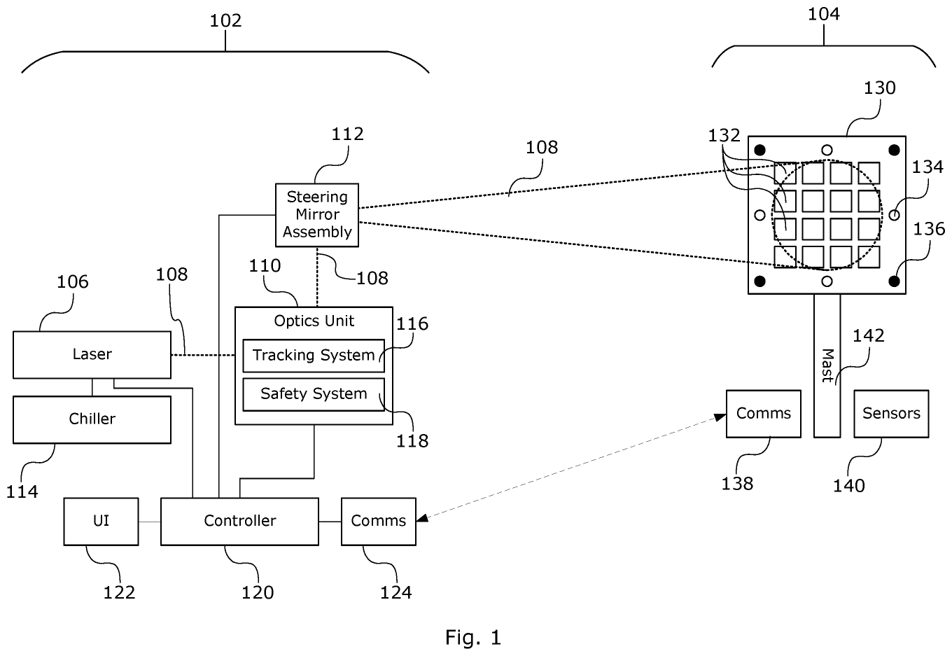

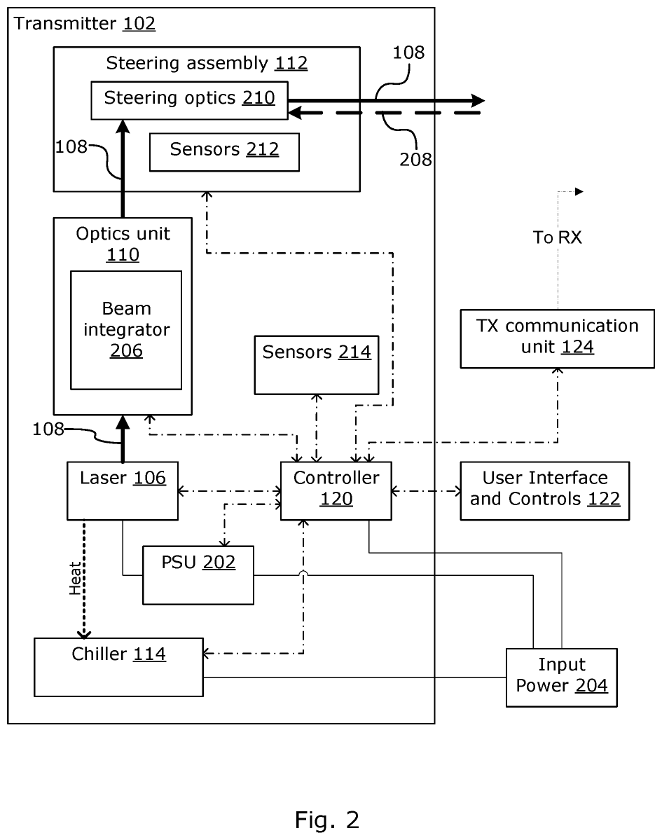

FIG. 1 is a schematic diagram of a power beam transmitter 102 and receiver 104. Laser 106 directs a power beam 108 (shown throughout the diagram as a dotted line) toward optics unit 110, which directs the beam to a beam steering assembly, such as mirror assembly 112. Optics unit 110 may include various lenses, mirrors, and other optical elements, as further discussed below. Steering mirror assembly 112 directs power beam 108 to power receiver 104. Optional chiller 114 is shown as connected to laser 106, but other components of transmitter 102 may also have independent or connected thermal management systems as required. Also shown in FIG. 1 as part of transmitter 102 are tracking system 116 and safety system 118. These systems are shown as being internal to optics unit 110 in the figure, but those of ordinary skill in the art will recognize that in some implementations, they may be external to optics unit 110, part of steering mirror assembly 112, or elsewhere in the transmitter system. Also shown are TX controller 120, user interface 122 and TX communication unit 124, all of which are further discussed below in connection with FIG. 2. It will be understood that transmitter 102 may include other elements, such as beam shapers, guard beams, or other appropriate accessory elements, that have been omitted from FIG. 1 for the sake of simplicity of the illustration. Some of these elements are shown schematically below in FIG. 2, but those of ordinary skill in the art will understand how to combine optical and control elements in a power transmitter.

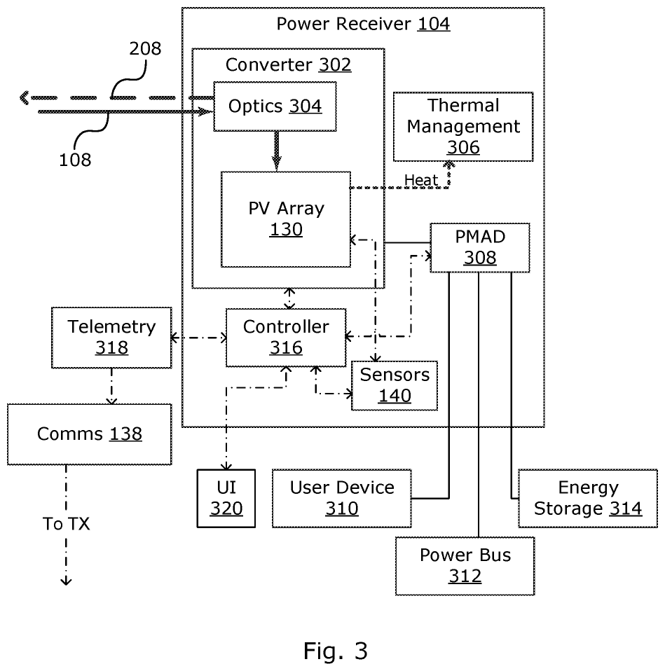

Receiver 104 in FIG. 3 includes a PV array 130, which includes a plurality of individual PV cells 132 (not all PV cells are labeled in order to avoid unnecessarily cluttering the figure). PV cells 132 convert incoming power beam 108 into electricity as further described below. Receiver 104 also shows tracking emitters 134, which in some implementations may be used by the tracking system 116 to monitor the position of PV array 130 for beam tracking or for other purposes. Receiver 104 also shows safety emitters 136, which in some implementations may be used by safety system 118 to monitor power beam 108 for potential intrusions, reflections, or other safety hazards. RX communication unit 138 is in communication with TX communication unit 124 (as indicated by the dashed line), and may be used for safety, tracking, telemetry, feedback control, or any other purpose for which it may be desirable for transmitter 102 and receiver 104 to communicate. While the illustrated embodiment provides communication across a separate channel such as a radio link between transmitter 102 and receiver 104, it is also contemplated that communication may be accomplished via modulation of power beam 108, tracking emitters 134, safety emitters 136, or other existing components of the power beaming system. Receiver 104 may also include optional RX sensors 140, further described below in connection with FIG. 3. As shown in FIG. 1, PV array 130 is mounted on optional mast 142, which may elevate receiver 104 to allow power beam 108 to avoid humans or other obstacles.

FIG. 2 is an abstracted diagram showing functional relationships between components of the transmitter. Transmitter 102 includes a laser 106, but it will be understood that other light-generating components, such as an LED or a magnetron, may be substituted for laser 106 in some implementations. Laser 106 is connected to controller 120, power supply unit (PSU) 202 (which is in turn connected to input power 204), and a thermal management system (chiller) 114. Throughout FIG. 2 and FIG. 3, heat flow is denoted by heavy dotted lines, while power beam 108 is denoted by a heavy solid line, sensor signals are denoted by heavy dashed lines, data and/or control signals are denoted by dot-dashed lines, and electrical power is indicated by a thin solid line. For the sake of clarity, not all internal electrical connections are shown.

Controller 120 controls operation of laser 106 and may be manual (for example using a user interface 122), partially automated, or fully automated, depending on design constraints of the system. In particular, controller 120 may receive input from a safety system, for example as described in commonly owned U.S. Pat. Nos. 10,634,813 and 10,816,694, U.S. patent application Ser. Nos. 15/574,659 and 16/079,073, International Patent Application No. PCT/US20/34104, and U.S. Provisional Application No. 63/140,236. The safety system may be designed to turn down or to turn off the beam, for example when an uninterrupted optical path from transmitter 102 to receiver 104 cannot be assured or when other hazardous conditions may be associated with continuing to beam power. Controller 120 may receive input (data) from other components, for example to monitor the health or temperature of the laser. PSU 202 draws power from input power 204, which may be, for example, a power grid, a generator, or a battery, and supplies it to laser 106. In the figure, controller 120 and chiller 114 are directly connected to input power 204, but in other embodiments, these or other components may receive power from power supply unit 202. Chiller 114 monitors the temperature of laser 106 (and/or other components of the transmitter as necessary) and makes sure it does not exceed safe values.

As shown in FIG. 2, power beam 108 emerges from light source 106 and enters optics unit 110. It will be understood that while light 108 maintains the same reference numeral throughout FIG. 2, the characteristics of light 108 may change in various ways (e.g., polarization, convergence/divergence angle, beam profile, or intensity) as it passes through different optics and other components. Optics unit 110 may include beam integrator 206 and other optics such as lenses, mirrors, phased arrays, or any other appropriate component for managing direction, divergence, and beam irradiance profile of the light, or for merging different optical power beams and/or signals. Beam integrator 206 will generally be chosen to match the wavelength domain of light source 106, and can be used to change the size, shape, or intensity distribution of the power beam. For example, when beaming power to a receiver, it may be desirable in some implementations to match the beam width to the size of the receiver, and possibly to “flatten” the beam irradiance profile to be relatively uniform across a surface of the receiver, for example converting a substantially Gaussian beam profile to a “top hat” or super-Gaussian profile. Beam direction and beam profile shaping is discussed in more detail in co-pending and commonly owned International Patent Application No. PCT/US20/34095. In particular, the mechanisms described therein for monitoring the placement of a power beam on a receiver and using the monitored data to feed back to controller 120 and/or to steering assembly 112 may be incorporated into the present system.

Steering assembly 112 may include steering optics 210 and/or sensors 212, which may be used in some implementations to provide feedback information for tracking the receiver and pointing the beam at it, to measure the beam characteristics such as direction or irradiance profile, or to monitor for potential intrusions into the light path. Steering assembly 112 may also include merging optics. Merging optics are generally used for combining multiple optical paths, or possibly for separating them when optical flow is in the opposite direction. For example, an outgoing power beam 108 for transmitting power may be combined with an incoming optical beacon 208 used for tracking a receiver, as shown in the figure. As illustrated, the beacon is used at steering assembly 112 for tracking, but in other implementations, signal 208 may propagate to optics unit 110 or beyond.

Transmitter 102 may also be provided with sensors 214, which may be used to monitor ambient conditions. Sensors 212, 214 may be used to adjust beam integrator 206 and/or steering optics 210. For example, sensors 212 might monitor position of a focusing lens or other optical component in steering assembly 112, while sensors 214 might be used to monitor ambient and/or other component temperatures. Data from sensors 212, 214 may be fed back into controller 120 to adjust laser 106, for example for safety considerations, or to control steering optics 210 and/or steering assembly 112 to direct beam 108 onto the receiver. Control and data signals may pass between controller 120 and other components, as shown by dot-dashed lines in FIG. 2, and controller 120 may control communication with the receiver, for example using transmitter communication unit 124.

After passing through optics unit 110, power beam 108 is directed by steering assembly 112 in a desired direction away from transmitter 102. In some implementations, steering assembly 112 may include steering optics 210, motors for adjusting mirrors or other components (not shown), and/or more shaping optics (not shown). Those of ordinary skill in the art will understand that different implementations may require different arrangements of optical elements (such as the order of components that the light passes through) without changing the fundamental nature of the transmitter system.

FIG. 3 shows functional relationships between components of a power receiver 104, such as the receiver shown in FIG. 1. Illustrated receiver 104 includes power converter 302, which includes PV array 130 of PV cells 132. Power converter 302 is configured to convert power beam 108 from laser 106 into electricity (or, in some implementations, into another useful form of energy). Receiver 104 may also include optics 304, which may shape or modify the received beam before it reaches PV array 130, for example as described in International Application No. PCT/US20/34093. In many implementations, PV array 130 includes a thermal management system 306. This system may include passive or active cooling, and it may be configured to send a signal back to transmitter 102 if any part of PV array 130 exceeds safe temperature limits (for example, via RX communication unit 138).

Power converter 302 may further be connected to power management and distribution (PMAD) system 308. PMAD system 308 may power user devices 310, a power bus 312, and/or energy storage devices 314. PMAD system 308 may be connected to controller 316, which may monitor PV array 130 via sensors 140, for example monitoring voltage, current, and/or temperature of individual photovoltaic cells, groups of cells, or of the whole array, voltage and/or current of the PMAD or of individual loads. Controller 316 may also include Maximum Power Point Tracking (MPPT) for PV array 130, or MPPT may be handled by PMAD system 308. PMAD system 308 may also include DC/DC converters, for example to provide power to devices 310, 312, 314 with preferred voltage and current characteristics. Telemetry unit 318 may send any or all of the above data back to the transmitter for use in controlling light beam 108, for example through RX communications unit 138. In some implementations, controller 316 may communicate with a receiver user interface 320, which may allow local viewing and/or control of receiver operations by a user of the power receiver.

Also visible in FIG. 3 is a signal 208 (e.g., an optical signal) being sent back to transmitter 102 by receiver 104, which may be sent along the same path as power beam 108 as shown. In some implementations, for example, signal 208 may include a safety signal that is used to assure an uninterrupted path from transmitter 102 to receiver 104. In some implementations, this signal may be sent from safety emitters 136. More details on safety systems may be found, for example, in commonly owned U.S. Pat. Nos. 10,580,921, 10,634,813, 10,816,694, and 11,105,954, U.S. patent application Ser. No. 16/079,073, and International Patent Application No. PCT/US20/34104. In some implementations, signal 208 may include a tracking signal that is used to position power beam 108 on power converter 302, such as a signal sent from tracking emitters 134. While signal 208 as shown in the figure is an “active” signal, in other implementations, emitters 134, 136 may be replaced by fiducial marks (not shown) that are identified by transmitter 102 or by other appropriate components in the power transmission system.

Any receiver components that require power, for example but not limited to thermal management system 306, RX communication unit 138, PMAD system 308, controller 316, telemetry unit 318, and/or user interface 320, may be powered by power converter 302 (directly or via PMAD 308) if desired. If components are powered by converter 302, the system might include a battery (either as part of energy storage 314 or as a separate component) to power these components during start-up or at other times when converter 302 is not supplying power.

### Waffle Board Layouts

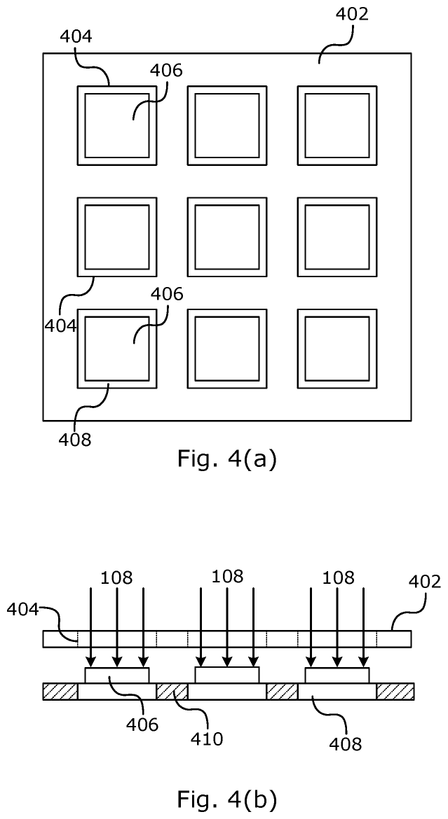

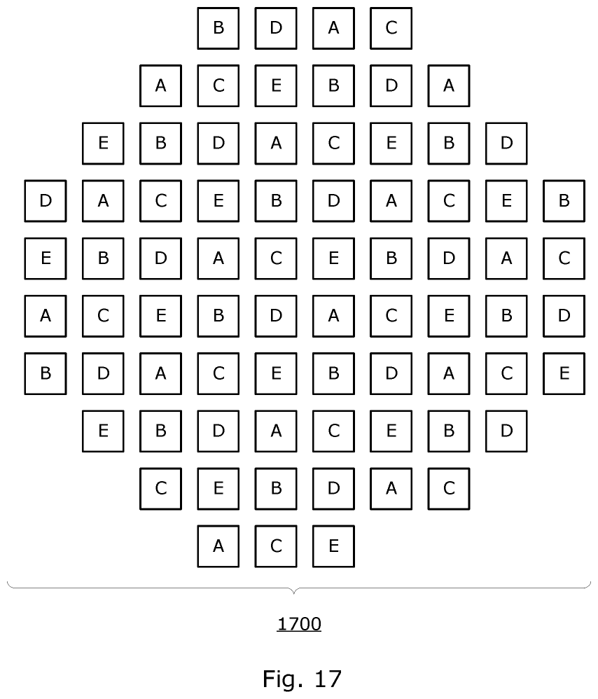

Referring to FIG. 4(a), circuit board 402 (hereinafter, “waffle board”) has a plurality of apertures 404 therein, through which may be seen PV cells 406. To avoid unnecessarily cluttering the figure, not all pictured PV cells are labeled, and fewer PV cells are depicted than may be present in a typical array. A PV array such as that shown in FIG. 4 might be as small as four PV cells, or it might be as large as 100 PV cells, 400 PV cells, or more. The illustrated array is square, but arrays need not have a square shape. As discussed below in connection with FIG. 17, an approximately octagonal arrangement of PV cells may be convenient, or other layouts may equally well be used. Those of ordinary skill in the art will understand that it may be advantageous in many implementations for the PV cell layout to have a shape similar to an expected shape of an impinging laser beam, which may be round, elliptical, square, or any other shape.

FIG. 4(b) is a side view of the same components as FIG. 4(a), and the two views may be referred to collectively herein as FIG. 4. As most easily seen in FIG. 4(b), PV cells 406 are mounted on a carrier 408. They are positioned with respect to waffle board 402 such that light 108 may pass through apertures 404 to reach PV cells 406. Circuitry (not shown) for connecting PV cells 406 to collect electric power generated by conversion of light 108 may conveniently be placed in or under carrier 408, or it may be located in or above shadowed areas 410, including as a part of waffle board 402. As illustrated in FIG. 4, apertures 404 in the waffle board 402 are slightly larger than PV cells 406, so that some portion of light 108 at the edges of the openings may strike carrier 408 rather than PV cells 406. While in some implementations this may be an advantageous arrangement, in other implementations, apertures 404 may be smaller (or PV cells 406 larger), so that substantially all of light 108 is directed onto PV cells 406. As illustrated, carrier 408 is a single piece, but in other implementations, PV cells 406 may be mounted on multiple carriers 408 (e.g., a separate carrier 408 for each PV cell 406, or a plurality of PV cells 406 on each of several carriers 408), which may in turn be fixed to a common substrate (not shown) or to one another.

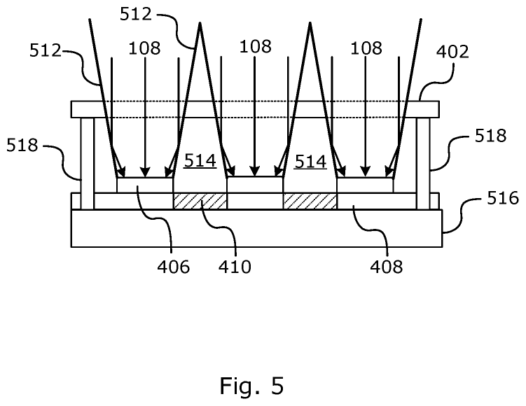

In some implementations, concentrators may be attached to waffle board 402. The use of concentrators with laser power beaming is more extensively discussed in copending and commonly owned patent application no. PCT/US20/34093, entitled “REMOTE POWER BEAM-SPLITTING,” which is incorporated by reference herein to the extent not inconsistent herewith. FIG. 5 depicts a side view of a waffle board 402 and shows concentrator reflectors 512, positioned to direct light onto PV cells 406. In other implementations (not shown), lenses, other configurations of reflectors (e.g., curved reflectors), or other optical components may be used to direct light onto PV cells 406. As shown in FIG. 5, “dead space” 514 may be used for electronics, heat management components, or other desired components of the receiver.

Waffle board 402 may include wiring to interconnect PV cells 406 with one another and/or with a load to be powered (not shown). In some implementations, waffle board 402 may be a multilayered circuit board, and wiring for different voltage levels (further discussed below) may be located on different levels of the multilayered circuit board. In some implementations, all wiring that varies for a specific application may be located in waffle board 402, so that an array of PV cells may be switched to a particular wiring scheme by swapping in an appropriate waffle board 402. Waffle board 402 (or other components of the system such as carrier 408) may also include dynamic wiring components, so that PV cell wiring may be switched programmatically, instead of being hard-wired into the system. This concept is further explored below in the section entitled “Dynamic Wiring.”

Also shown in FIG. 5 is a heat sink 516. In some implementations, heat sink 516 may be used as a mechanical reference for optical components when constructing the receiver. In such implementations, heat sink 516 may be flat to within a selected tolerance for the receiver, and all other components (e.g., waffle board 402, PV cells 406, carrier 408, reflectors 512) are positioned relative to the heat sink 516. Optical reference surfaces are well known for interferometers and the like, where they are typically flat to a fraction of the wavelength of light for which they will be used, such as λ/4 or λ/20 (typically around 100 nm) across the width of the component. When heat sink 516 is used as a mechanical reference, this degree of flatness is typically not needed, and heat sink 516 may be flat to within 25 μm, 100 μm, or even 1 mm or more across the width of heat sink 516. In these implementations, heat sink 516 may be used not only as a reference for vertical alignment, but also for horizontal alignment of PV cells 406, waffle board 402, carrier 408, a carrier substrate (not shown), concentrators 512, or any other components of the system. FIG. 5 also shows mechanical supports 518 at the edges of the array, where they anchor waffle board 402 in a fixed position relative to heat sink 516. It will be understood that these mechanical supports may be placed at any location and with any convenient spacing so that they hold waffle board 402 in a correct position relative to heat sink 516. An advantage of using heat sink 516 as the reference is that it is often physically large and constructed of metal or other rigid materials, although neither of these properties is required to use it in this fashion.

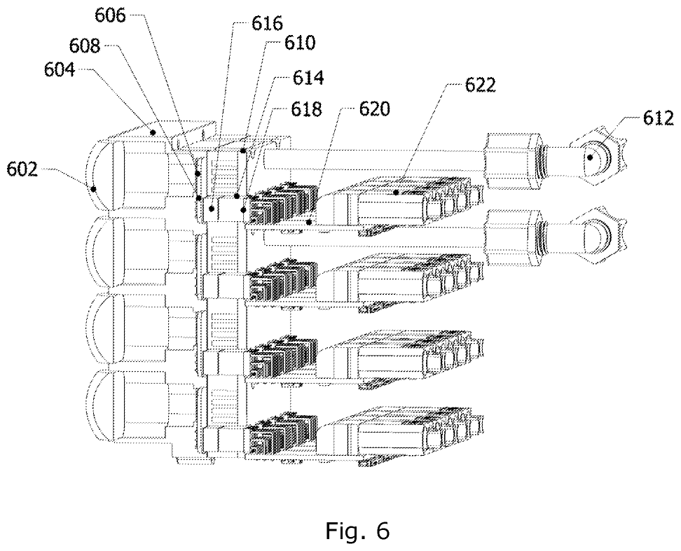

FIG. 6 is a schematic representation of a receiver including a perforated heat sink. This configuration allows separation of the PV cells from electronic components so that the heat sink may be placed closer to the PV cells for efficient cooling, while leaving plenty of space for electronics behind the heat sink. Another advantage of this configuration is that all of the PV cells may be at close to the same temperature, which may improve the efficiency of power conversion. The receiver includes optical elements 602 that are the first elements to encounter an incoming power beam. Such optical elements may include, for example, lenses, mirrors, filters, windows, optical flats, prisms, polarizers, beam splitters, wave plates, fiber optics, and retroreflectors. The power beam passes through chamber 604 to reach PV cells 606, where it is converted to electricity as discussed below. PV cells 606 are mounted on a PV carrier 608, which in the illustrated implementation is a printed circuit board. Other implementations may use carriers made of metal, plastics, or other appropriate materials known in the art. PV carrier 608 is in thermal contact with heat sink 610, for example by being mounted on the heat sink or being connected to it by a thermally conductive element. In some implementations, PV carrier 608 may be absent and PV cells 606 may be mounted directly on heat sink 610. Even when PV cells 606 are on PV carriers 608 that are in contact the heat sink, the cells may be described as “mounted on” heat sink 610.

In the illustrated implementation, heat sink 610 is a water block, but other implementations may use heat pipes, vapor chambers, solid metal components, solid composite materials such as encapsulated graphite, or other heat transfer structures known in the art. Water block 610 in FIG. 6 is connected by cooling water connections 612 to a water source. Water is flowed through the portion of the block adjacent to PV cells 606, and transports heat generated by PV cells 606 away from the block. In other implementations, other cooling fluids may be used to transport heat, and other configurations of heat sink 610 are also contemplated. For example, if heat sink 610 is a vapor chamber or a heat pipe, then heat may be used to vaporize a cooling fluid, which is transported away from PV cells 606 and condensed for recirculation.

Heat sink 610 includes a plurality of apertures 614, through which electrical connectors 616 pass. Electrical connectors 616 are connected at one end to output terminals of PV cells 606, and at the other end via connectors 618 (shown as pins in the figure) to PV interface boards 620. Each PV interface board 620 may be connected to one or to multiple PV cells 606. In some implementations, for example, a PV cell having a relatively low voltage/high current output (for example, a single-junction PV cell) may be connected using a plurality of electrical connectors 616, while in other implementations, a PV cell having a relatively high voltage/low current output (for example, a multi-junction PV cell) may be connected using fewer electrical connectors. PV interface boards 620 may perform a variety of electrical functions. For example, they may include electrical sensors such as current or voltage sensors, which may be used to monitor the current, voltage, and/or power from individual PV cells 606 or from aggregates of PV cells 606. They may also include environmental sensors (e.g., measuring temperature or humidity), which may include directly measuring environmental parameters at the PV connector board and/or accepting input from sensors placed in the vicinity of PV carriers 608 or elsewhere in the receiver. Sensor signals may be used locally to control operation, and/or they may be sent to telemetry unit 318 for communication to a power beam transmitter 102 as discussed above. PV interface boards 620 may include DC/DC converters or regulators such as voltage boost circuits and/or MPPT circuits. In FIG. 6, they are further connected to electrical power output connectors 622, which may be used to store energy in a battery and/or directly connected to a load.

By placing heat sink 610 close to PV cells 606 and passing electrical connectors 616 through heat sink 610 to electronics placed farther away from PV cells 606, the illustrated arrangement allows heat generated at PV cells 606 to be efficiently removed from the system, while leaving plenty of space for electronics. While electronics on PV interface boards 620 may also be cooled by heat sink 610 (or by another heat sink) in some implementations, PV cells 606 may frequently be the most significant source of waste heat to be removed from the receiver. In some implementations, heat may also be generated by portions of the power beam that “miss” light-collecting surfaces of PV cells 606, and this heat may be removed by heat sink 610 as well. Placing heat sink 610 in the vicinity of PV cells 606 may allow their temperature to be regulated to improve power generation.

In the illustrated implementation, heat sink 610 serves as an indexing surface for PV carriers 608 and for sidewalls of chambers 604, which in turn determine the positions of PV cells 606 and optical elements 602. This indexing allows optical elements 602 to be positioned precisely relative to PV cells 606, so that cells 606 may be placed at a desired location, for example near a focal point of a lens. This concept is further discussed in co-pending and commonly owned U.S. Provisional Patent Application No. 63/140,256.

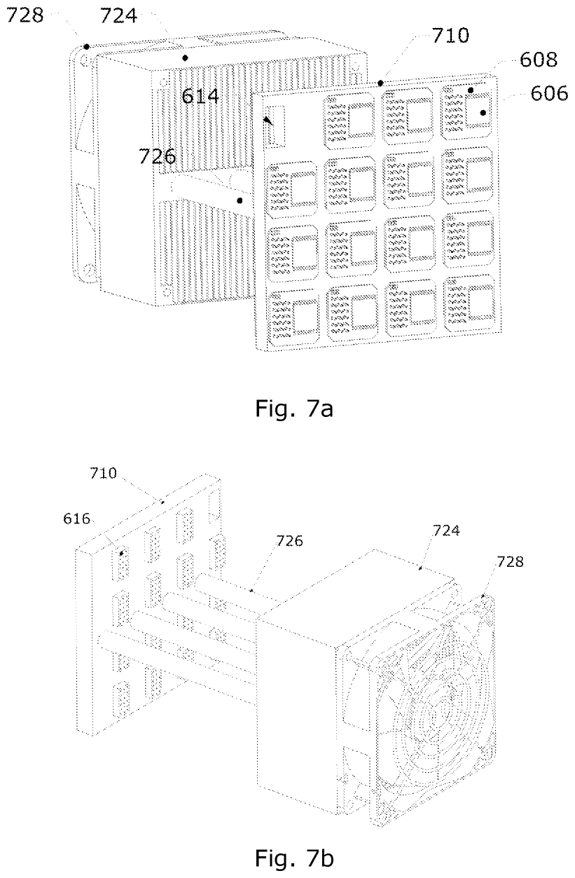

FIG. 7 is a schematic diagram showing another implementation of the power receiver. FIG. 7a is a top view, and FIG. 7b is a bottom view. (Optics 602 and chambers 604 have been omitted from the figure for clarity, but this implementation may still include optics if desired.) As shown in the figure, heat sink 710 is a vapor chamber placed in contact with PV carriers 608 as discussed above. Heat sink 710 may be connected to cooling fin assembly 724 by heat pipes 726. Cooling fin assembly 724 includes a plurality of fins, which are cooled by forcing air over the fins using cooling fan 728. In some implementations, cooling fan 728 may not be needed, for example if the receiver is being used in a moving vehicle or if natural convection is sufficient. In some implementations, heat sink 710 and heat pipes 726 may be replaced by a 3D vapor chamber having a substantially similar outer shape, but with a unified shared vapor space, which may provide a lower thermal resistance between the PV carriers 608 and cooling fin assembly 724.

### Distributed Wiring Arrangements

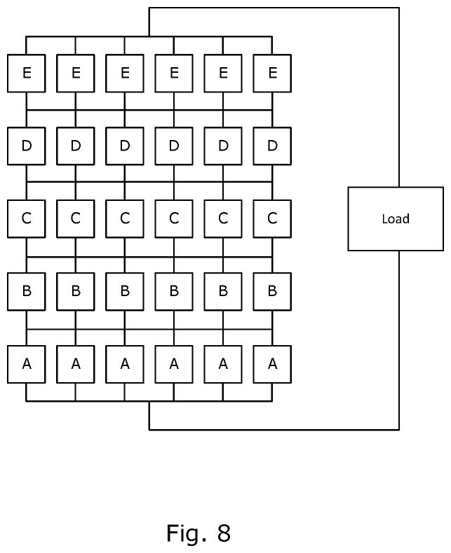

Because each PV cell in a PV array generates a relatively small voltage compared to typical loads, PV arrays are typically wired to place some PV cells in series with one another, adding their voltages to a more usable output voltage. In some arrays, “strings” of PV cells are wired in series, and then the strings are wired in parallel, thereby adding the string output currents. In other arrays, PV cells are wired in parallel, and then the parallel strings are wired in series as further described below, as illustrated in FIG. 8. As explained by Kare in U.S. provisional patent application No. 60/999,817, entitled “Photovoltaic Array” (hereinafter, “Kare”), the former type of array performs efficiently if all PV cells within a series-wired string produce equal current. If one PV cell in a string produces no output due to damage or shadowing, it may be bypassed by a bypass diode, reducing the current for that string but losing only slightly more total output power from the array than that one PV cell produced. However, if the PV cells are illuminated with varying amounts of light, the current in the series string will be limited by the least-illuminated PV cell that is not reverse-biased. We note that this is not generally a problem for a solar array, which will typically be evenly illuminated, but when a PV array is illuminated by a laser beam which may be spatially nonuniform or may move relative to the array, this effect may limit the efficiency of power production.

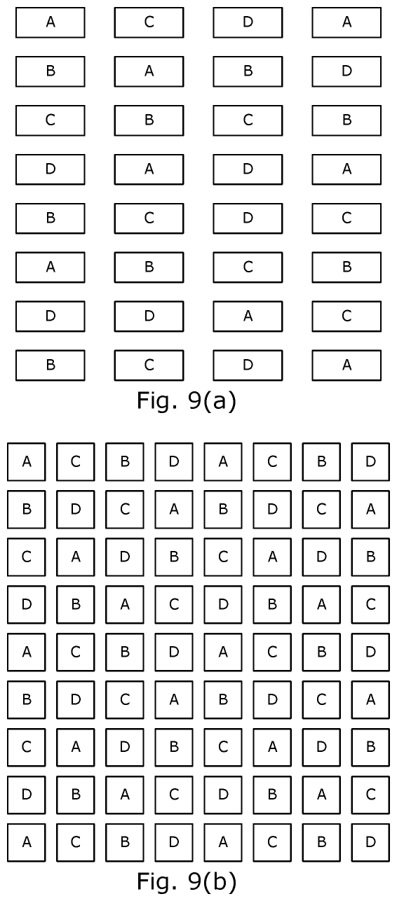

Kare described a system of physically distributing parallel-wired PV cells across an array surface. It is noted that the arrays shown herein, both those drawn from Kare and the innovative arrays we describe below, have the electrical wiring schematic shown in FIG. 8, but the physical positions of the PV cells of each array differ from layout to layout. Kare disclosed a randomly arranged array, where PV cells at each of four voltage levels are spread across the array surface, and also a “staggered” array, where PV cells are divided into strings and groups that may be split across columns. The random array is shown for reference in FIG. 9(a), and the staggered array is shown in FIG. 9(b). (FIG. 9(a) and FIG. 9(b) may be referred to collectively herein as FIG. 9.) In these figures, the shape codes of Kare have been replaced with letters representing the voltage levels for each PV cell. With respect to FIG. 9(b), Kare described in his FIG. 5 a 4×9 array of rectangular PV cells, which is shown as “doubled” in FIG. 9(b) to form an 8×9 array of square PV cells instead. Kare describes repetition of arrays in this fashion in the paragraph spanning pages 3-4. The arrays illustrated in Kare use rectangular PV cells with a significant spacing between them, while most of the new arrays described herein are illustrated with square PV cells with little or no space between them. Arrays of the latter type may use concentrators to capture substantially all incident light (as shown in FIG. 5), or may simply be placed very close together, so that light falling between the PV cells is minimal.

The arrays of FIG. 9 will be compared with new arrays in the following discussion, as will pre-Kare arrays of parallel-wired strings of PV cells, with the PV cells wired in series within each string. Kare did not describe how to generalize its arrays to larger sizes (other than by repetition as mentioned above), nor did it describe any rules for creating additional PV array layouts beyond two examples. We provide below principles for creating new PV array layouts with superior performance.

There are a number of external factors that affect the number of voltage levels for a PV array design using parallel wiring for groups of PV cells. In particular, there may be a desired total output voltage for a design load, or limits on the minimum or maximum voltage that the load can handle. The nominal output voltage of a PV cell divided into that desired output voltage will usually guide the number of voltage levels, but other factors to consider include the desired size of the PV array, the desired number of PV cells in the array, the ways in which a specific number of voltage levels may be evenly divided between that quantity of PV cells, and the provision of optional DC voltage converters and regulators (further discussed below). The arrays of Kare were shown with four voltage levels, but we have found in at least some cases that five or six levels may allow us to avoid having to install voltage converters, thereby saving space and weight for PV arrays. In some implementations, power receivers may be incorporated into mobile components that can drive or fly from one place to another, so weight may be a very important consideration in receiver design for such implementations. Even more voltage levels may be preferable in certain implementations: we have envisioned an array having as many as 75 voltage levels with four to ten PV cells (or more) per level. However, we expect that for most uses, six to 30 voltage levels will be sufficient, and as few as four to six may be suitable in many cases.

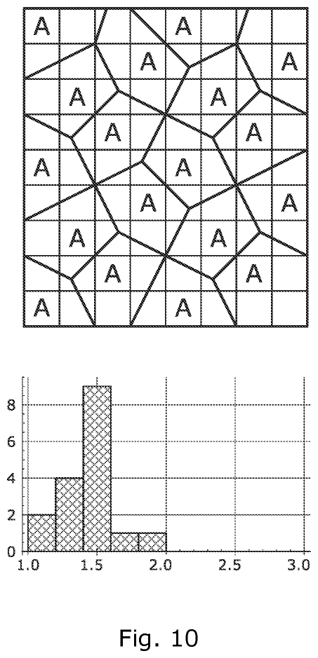

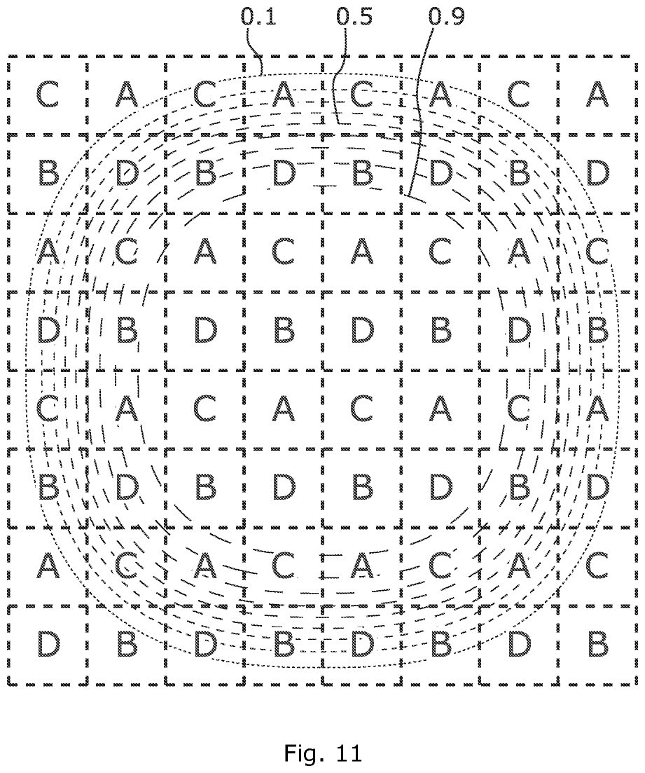

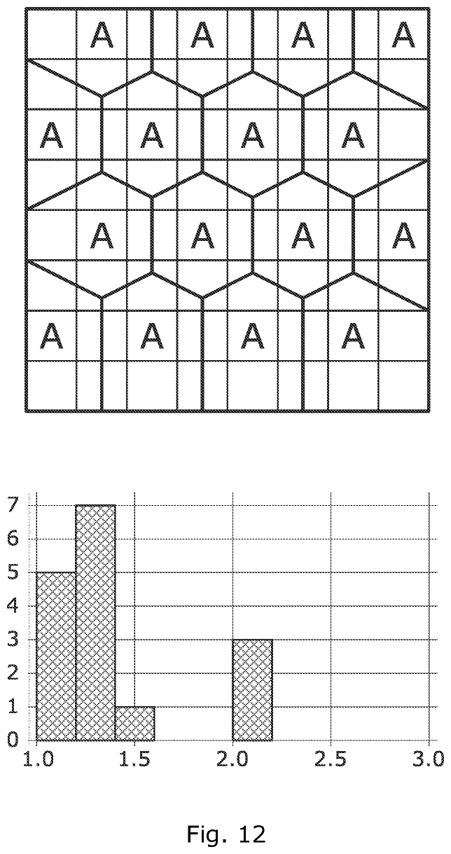

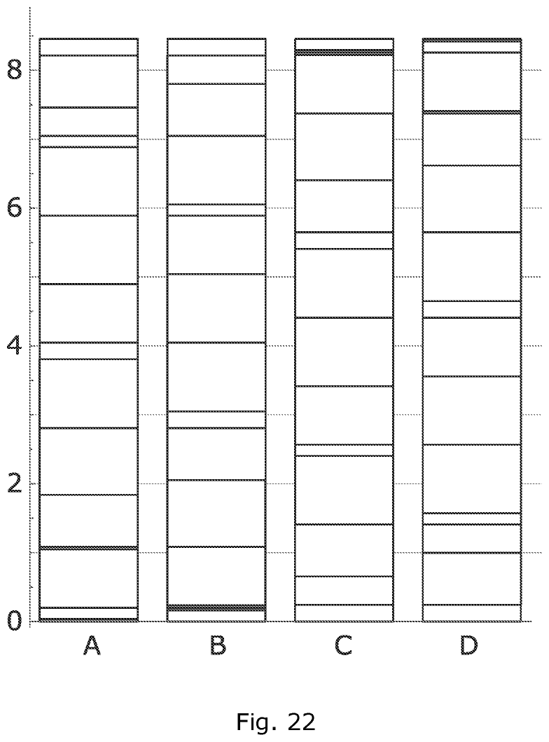

Generally speaking, we have found that the arrays that perform best when exposed to beam wander and beam intensity profile variation have the PV cells for any one level “evenly” distributed in space across the PV array. A metric we have used to determine the evenness of this distribution is to use the centers of PV cells at each voltage level to generate a Voronoi mesh, and then to look at the aspect ratios of the Voronoi cells in the mesh. We have found that the best-performing arrays have Voronoi cell aspect ratios as close as practical to 1.0, preferably having a median aspect ratio of less than 1.5, more preferably less than 1.3, or even more preferably less than about 1.1. FIG. 10 shows Voronoi meshes for the Kare array shown in FIG. 9(b), and also shows a histogram of the pictured Voronoi cell aspect ratios; the histogram shows Voronoi cell aspect ratios ranging from 1.3 to 2.2, with the median-shaped Voronoi cell having an aspect ratio of 1.5. For comparison, a mesh for a new array that will be discussed below in connection with FIG. 22 is shown in FIG. 11; its accompanying histogram in FIG. 12 shows Voronoi cell aspect ratios ranging from 1.0 to 2.6, with the median-shaped Voronoi cell having an aspect ratio of 1.31. We note that the Voronoi cells having the highest aspect ratios often appear at the array edges.

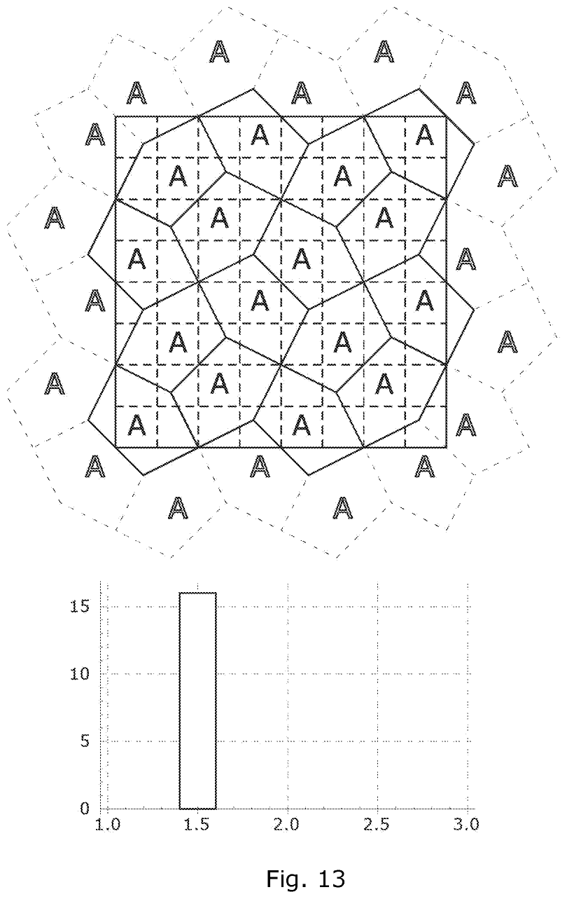

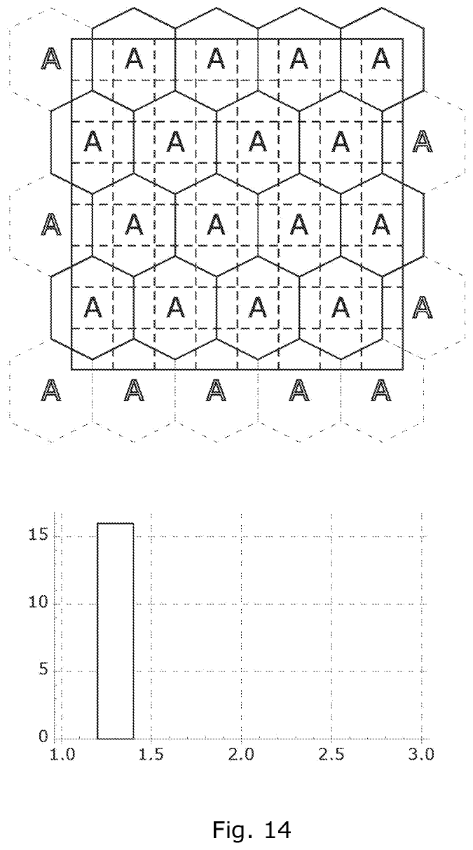

In some implementations of our array design process, we may “extend” a pattern of voltage levels beyond the edges of the physical array for purposes of making the Voronoi cell calculation. For example, instead of an 8×8 array as shown in FIG. 9(b), we determine Voronoi cells for a 12×12 array using them same regular pattern, and then determine the aspect ratio only of the cells corresponding to the members of the center 8×8 array, yielding the revised Voronoi diagram and corresponding aspect ratio histogram shown in FIG. 13. A similar extension of the array shown in FIG. 11 leads to the Voronoi diagram and corresponding aspect ratio histogram shown in FIG. 14. This extension may avoid artifacts at the edges of the array where cells appear to have larger aspect ratios; in each of FIG. 13 and FIG. 14, all of the Voronoi cells have the same aspect ratio. Even with these expanded diagrams, however, the array illustrated in FIG. 14 has cells with a lower aspect ratio than those shown in FIG. 13.

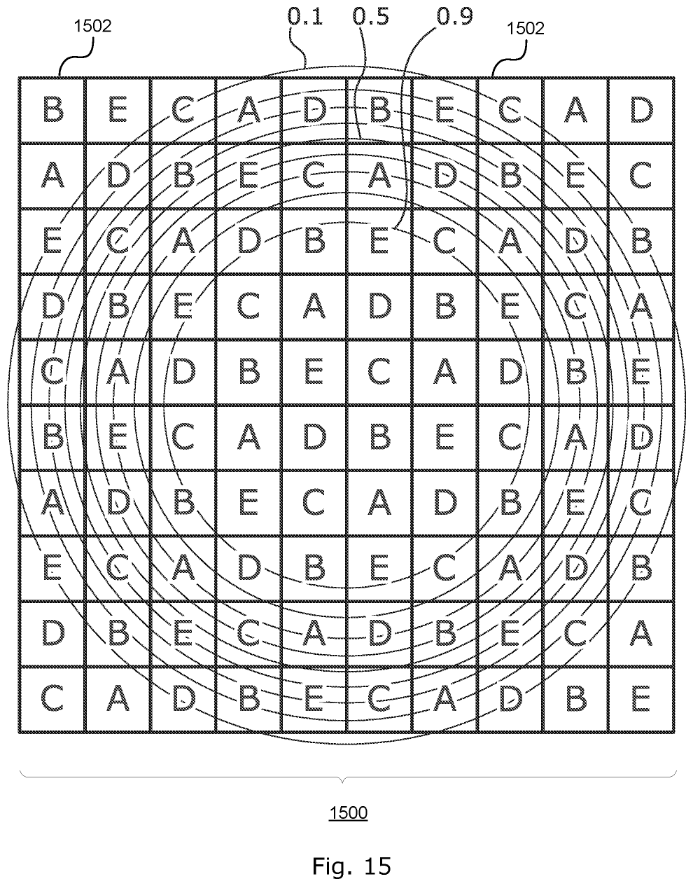

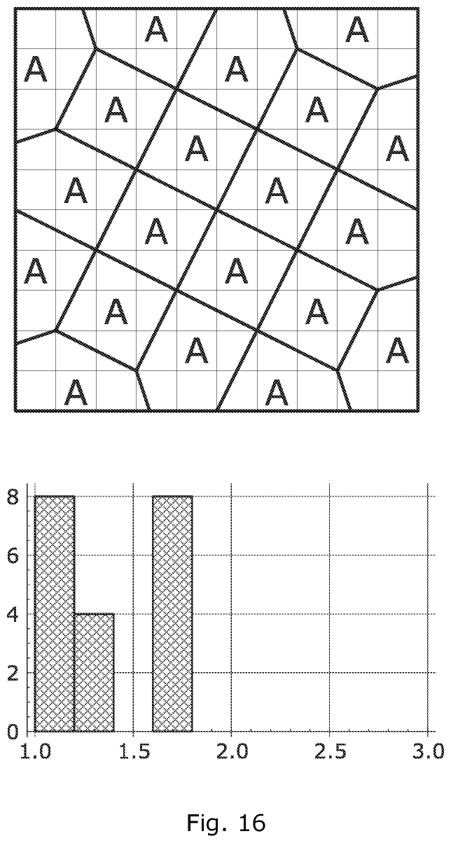

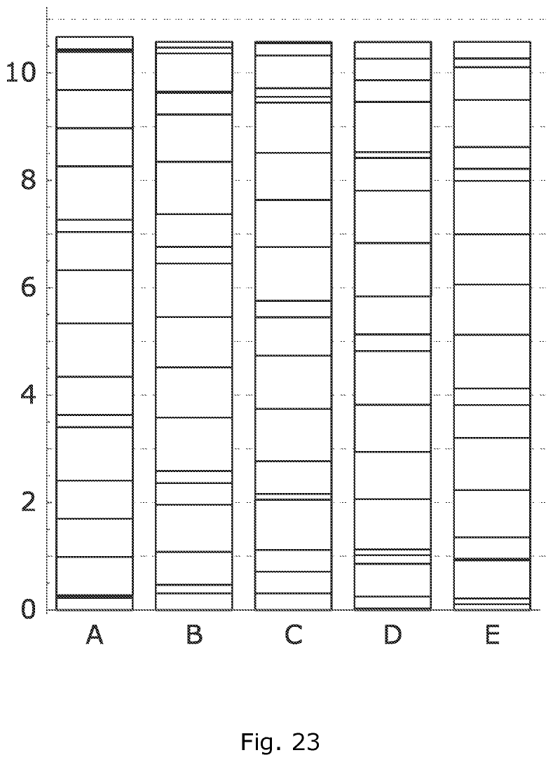

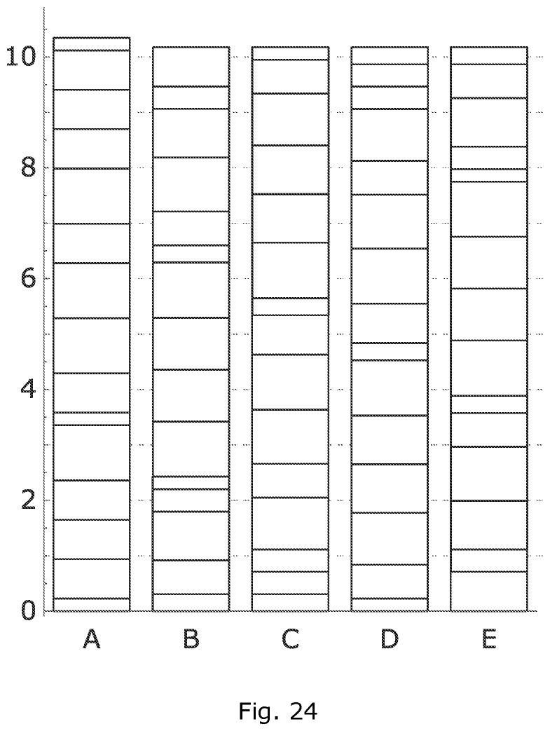

To achieve array layouts with evenly spread PV cells at each voltage level, one method we have used is to create “staggered” arrays, which repeat a pattern of PV cell voltage levels in each column, with an offset for each so that the same PV cells will not be adjacent to one another horizontally or vertically. (While the Kare array shown in FIG. 9(b) has been described therein as “staggered,” it does not have a constant offset from column to column. As used in the present application, a “staggered” array means one with a constant offset from column to column unless context clearly dictates otherwise.) As used herein, the term “adjacent” means having an adjacent edge, and “diagonally adjacent” means having an adjacent corner, like the two A-level cells in FIG. 9(a) at the top left of the figure. If two PV cells are described as “not adjacent,” they may still be diagonally adjacent unless further restrictions are added. One staggered array 1500 is shown in FIG. 15. PV cells 1502 are arranged in a 10×10 array and are labeled to show which of five voltage levels that they belong to. As shown, the PV cells in successive columns are staggered with an offset of 2: that is, the horizontally-adjacent PV cells will be at level −2 to the right of a column and +2 to the left (modulo 5); this produces an array arrangement in which no two PV cells 1502 are either adjacent or diagonally adjacent. Contour lines shown on FIG. 15 will be discussed below in connection with FIG. 23 and FIG. 24. FIG. 16 shows the Voronoi cells for current level A, and a histogram of aspect ratios of Voronoi cells in FIG. 16 is also shown. The median aspect ratio for Voronoi cells in this array is 1.33 (as shown in Table 1). Those of ordinary skill in the art will appreciate that many possible combinations of the size of the array, the number of voltage levels, and the offset may be chosen. In order to produce Voronoi cells having a low aspect ratio, it is believed that the offset should be greater than one and at least two less than the number of voltage levels. It is also believed that the offset and the number of voltage levels should have a greatest common divisor (GCD) of one, but some layouts with a greater GCD may also produce Voronoi cells having an adequately low aspect ratio.

Another array 1700 is shown in FIG. 17. This array is also based on a 10×10 array like the one in FIG. 15, but the corner PV cells have been removed from the array. This shape has been found advantageous for use with a beam having approximate circular symmetry. It will be noted that symmetric removal of the corners may change the number of PV cells in each voltage group so that they are no longer equal. While it may be possible or even advantageous to construct a PV array with different numbers of PV cells in each voltage level in some implementations, generally it has been found to be advantageous to maintain the same number of PV cells in each level if possible. A “perfect” arrangement of a 10×10 array of PV cells with six PV cells removed at each corner would leave 76 PV cells, which cannot be divided evenly into five voltage levels. For this reason, one PV cell that would otherwise be in level B has been omitted at one edge of the array, visible at lower right in FIG. 17. PV cells at the array edges are generally expected to contribute less to total power transmitted because beams often (but not always) have a higher intensity at the center than at the edge.

The array shown in FIG. 17 has been modeled theoretically as discussed below, but it also has been physically constructed and used for FSP power beaming. As discussed in connection with FIG. 4 and FIG. 5 above, the physical array includes a waffle board 402 that is a multilayered circuit board, where connections for PV cells 406 of different voltage levels are separated into different layers of the circuit board. Individual PV cells 406 are connected only to a carrier 408, which also includes a thermistor for monitoring PV cell temperature, and not directly to other PV cells. All connections between PV cells (as well as the temperature monitoring signal from the thermistor, not shown) are located within waffle board 402. In this type of implementation, new PV cell layouts as discussed herein can be rapidly implemented simply by designing and fabricating a new waffle board 402, while leaving all other components unchanged.

We have compared models of our arrays generated as described above to models of the Kare arrays to examine the quality of each. Although current output from a PV cell is a function of the PV cell's I-V curve at a given illumination intensity and temperature and is not a single, fixed value, for purposes of modeling and comparison we assume that PV cells are operating near their maximum power point, and that intensity of illumination can be translated directly and approximately linearly into an output current. For each voltage level in an array, we define a “level current” that is the sum of currents from all of the PV cells in that voltage level. Just as each PV cell in a single series string should be equally illuminated so as to match the currents, an array will generally perform best when the level currents of each voltage level are approximately equal. Stated another way, the differences between level currents are preferably minimized. Ideally, a PV array would be designed so that the minimized differences between level currents are robust against power beam intensity profile variations or wander of the beam centroid—that is, that when the beam wanders slightly or its profile changes, changes of the differences between the level currents are minimized. Using the assumption described above that the current out of a PV cell is roughly linearly proportional to the input power, then for purposes of estimating the nominal current out of each PV cell our model uses the incident light on the PV cell as a proxy for PV cell current. The following description may use the terms “intensity,” “power,” “power intensity,” “current,” or “current density” interchangeably, since they are all assumed to be proportional to one another in our model.

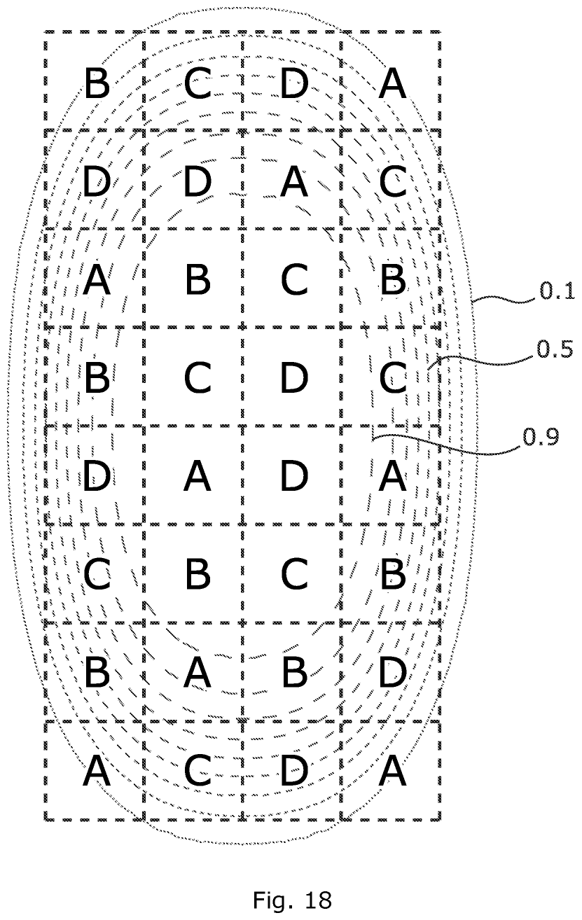

To characterize our test arrays, we define “mismatch” as the difference between the maximum current and the minimum current, divided by the mean current and expressed as a percentage. We use the light intensity at the center of a PV cell as a proxy for its output current, since the total power across a PV cell's collection area is substantially equivalent to the power at its center for nonpathological beam intensity profiles. A more complete model might use intensity integrated across the area of the PV cell, but we have modeled this difference and found it to yield only negligible improvements, so we use the intensity at the PV cell center for computational simplicity. We then generate a “virtual” light beam profile with parameters to describe its width in major and minor axes, rotation angle relative to the PV array, an amount to which it approximates a rectangle or an ellipse, and an intensity profile (which is generally modeled as a super-Gaussian shape, with the super-Gaussian factor as one of the parameters). We use Monte Carlo methods to simulate moving and/or rotating the beam, and/or changing its profile. FIG. 18 shows an example beam profile designed to roughly approximate the shape and size of the Kare array shown in FIG. 9(a). The applied beam profile is elongated to match the aspect ratio of this 4×8 array, as shown in the illustration.

Our centered virtual light beam profile can be described by six input parameters as follows: wₓ and w_{y} represent the beam width in the x and y directions. θ represents the rotation of the beam in the x-y plane, and nₓ, n_{y}, and n_{sG} represent super-Gaussian parameters of the beam profile. nₓ and n_{y} apply separately to the x and y components and the larger these two parameters are, the closer the beam profile is to a rectangle than an ellipse. n_{sG} is the normal super-Gaussian factor, and the larger it is, the closer the beam profile is to a “top hat” profile instead of regular Gaussian. Beam intensity at a given location is then described by the following parameters:

Let a, b, and c be defined as follows:

$$a = \frac{{cos}^{2} θ}{2 {w}_{x}^{2}} + \frac{{sin}^{2} θ}{2 {w}_{y}^{2}}$$

$$b = \frac{- sin 2 θ}{4 {w}_{x}^{2}} + \frac{sin 2 θ}{4 {w}_{y}^{2}}$$

$$c = \frac{{sin}^{2} θ}{2 {w}_{x}^{2}} + \frac{{cos}^{2} θ}{2 {w}_{y}^{2}}$$

Intensity J at a point x, y is then described by:

$$J = {J}_{0} {e}^{- {( {a ( {x}^{2} )}^{{n}_{x}} + 2 b x y + {c ( {y}^{2} )}^{{n}_{y}} )}^{{n}_{s G}}}$$

For the purpose of comparing relative array performance, mainly with the mismatch, the absolute intensity value is irrelevant and so for ease of modeling the peak intensity J₀ is simply set to 1. In our Monte Carlo simulation, we then allow the beam to wander in the x- and y-directions, choosing positions with an applied error having a normal distribution with a selected standard deviation (shown in Table 1 as “Beam wander,” which is expressed as a fraction of PV cell width), might be expected to occur naturally due to various sources of “noise” (from tracking, signal processing, mechanical motion, etc.) for a beam steering system. Note that the random position error is generated (in a normal distribution) separately for the x and y position errors. The above equation is shifted in the x,y plane to determine the intensity at the center of each PV cell location. 200 Monte Carlo runs were performed for each of the various cases discussed below. Table 1 shows the array parameters, beam profile, and Monte Carlo input factors for each case described below, along with relevant performance results.

TABLE 1

| | FIG. 8 | FIG. 9(a) | FIG. 9(b) | FIG. 11 | FIG. 15 | FIG. 17 |
|---|---|---|---|---|---|---|
| Number of voltage | 5 | 4 | 4 | 4 | 5 | 5 |
| levels | | | | | | |
| Array “size” | 6 × 5 | 4 × 8 | 8 × 9 | 8 × 8 | 10 × 10 | 10 diameter |
| | | | | | | “round” |
| Number of PV cells | 30 | 32 | 72 | 64 | 100 | 75 |
| Voronoi median | n/a | 1.88 | 1.5 | 1.25 | 1.33 | n/a |
| aspect ratio | | | | | | |
| wₓ | 6.2 | 3.8 | 8.3 | 8.3 | 6.2 | 6.2 |
| w_{y} | 6.2 | 7.6 | 10.2 | 8.3 | 6.2 | 6.2 |
| θ | 0 | 0 | 0 | 0 | 0 | 0 |
| nₓ | 1.0 | 1.2 | 1.3 | 1.3 | 1.0 | 1.0 |
| n_{y} | 1.0 | 1.2 | 1.3 | 1.3 | 1.0 | 1.0 |
| n_{sG} | 2.5 | 2.2 | 2.5 | 2.5 | 2.5 | 2.5 |
| Beam wander | 0.2 | 0.125 | 0.15 | 0.15 | 0.2 | 0.2 |
| Centered beam | 26.5% | 22.1% | 5.6% | 0% | 0.9% | 1.6% |
| mismatch | | | | | | |
| Monte Carlo | 26.3% | 22.0% | 6.2% | 1.7% | 1.1% | 2.7% |
| mismatch | | | | | | |

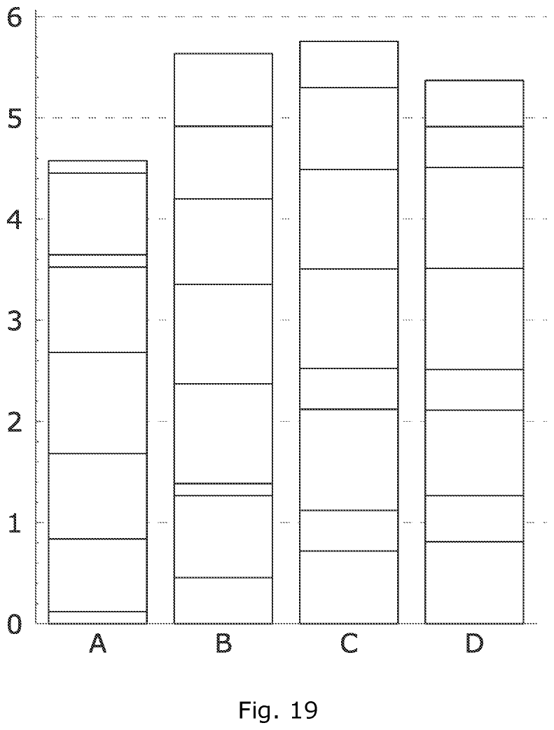

When the Kare array depicted in FIG. 9(a) is modeled as described above, it performs relatively poorly, showing a mismatch of 22.1% for the beam profile shown in FIG. 18. The beam profiles in FIG. 18 and other figures show contour lines of constant intensity, ranging from 0.1 up to 0.9 (because the peak of 1.0 might be a single point in the middle of the beam, and low intensity below 0.1 out in the tails of the profile makes showing contours below 0.1 not important for this application). FIG. 19 shows stacked currents for each of the four voltage levels when the beam in FIG. 18 is centered on the array. Each white bar in FIG. 19 represents the current from a single PV cell, which are added together to form a total output current represented by the height of the stacked bars in each column for these parallel-wired PV cells. The mismatch (shown in Table 1) is apparent by inspecting the graph of FIG. 19, and indicates that the array shown in FIG. 9(a) substantially inferior to the arrays further described below. Ideally, each of these total currents shown in FIG. 19 would be the same, rather than stacking to different heights as shown.

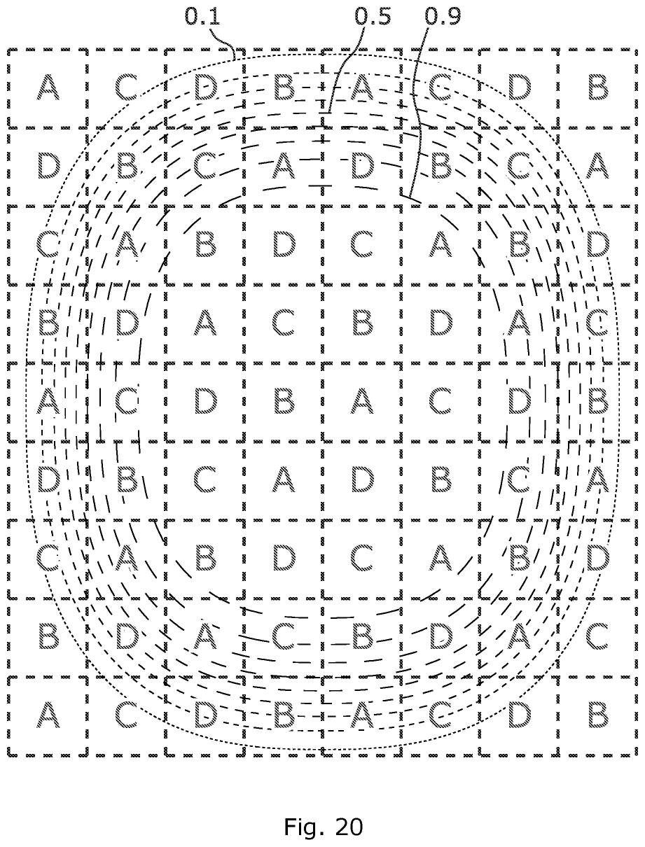

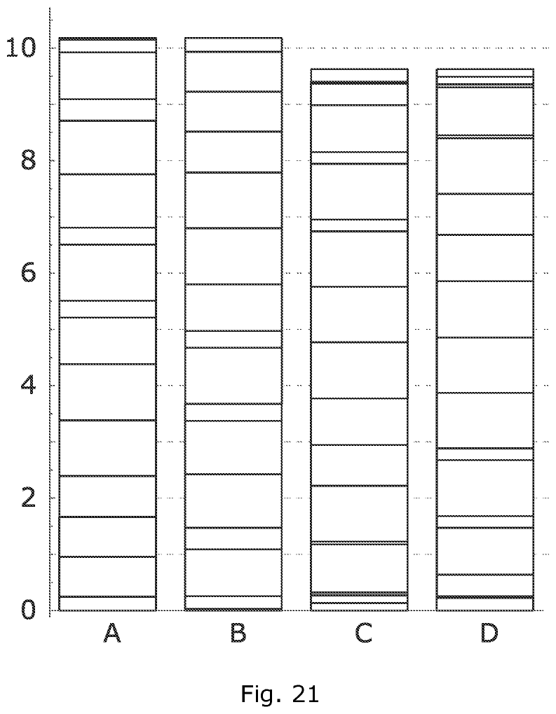

When modeling the array shown in Kare FIG. 5, in order to more closely compare it with our arrays, which typically have overall aspect ratios near 1, we “doubled” the array (as suggested in Kare in the paragraph spanning pages 3-4), placing two identical arrays side-by-side to create a 9×8 array of PV cells (instead of the 9×4 array of Kare) as shown in FIG. 9(b), and used a slightly eccentric beam profile to match the slightly non-square shape of the array. The beam shape and size were defined as described above, with the parameters listed in Table 1, and the x and y positions were varied in a Monte Carlo simulation as described above with a standard deviation listed in Table 1. One profile from the simulation is illustrated in FIG. 20: the size and eccentric chape of the beam profile are visible in the contour lines. This shape reflects a beam profile that might result when the beam designer tries to make a rectangular beam to match the array shape (Kare shows substantially rectangular beams), The stacked currents for each of the four voltage levels for the illustrated profile are shown in FIG. 21. The mismatch for this test configuration is less than that of the other Kare array, but still relatively high: 5.6% in the illustrated run and averaging 6.2% over all runs of the Monte Carlo simulation.

For closest comparison with the array performance shown in FIG. 21, we created an 8×8 array with four voltage levels, constructed using the design principles described above, as shown in FIG. 11. We used an 8×8 array (instead of a 9×8 array as in Kare) because it is more common to have a beam with an aspect ratio of 1 and therefore a receiver that has the same width and height, and in order to maintain a constant offset of 2 while still having the same number of PV cells at each voltage level. FIG. 22 shows stacked currents for the beam centered on the array as shown in FIG. 11. For the same beam profile shown in FIG. 20, mismatch was zero. The mismatch averaged over the simulation for all runs of this array was 1.7%, showing significantly better performance than the Kare array.

By comparison, FIG. 23 and FIG. 24 show the same stacked currents graph for the centered-beam case for arrays shown in FIG. 15 and FIG. 17, respectively (i.e., the 10×10 array with 5 voltage levels, and that same array with some PV cells near the corners removed). Analogously to FIG. 11, FIG. 15 shows the substantially circular beam profiles used in modeling the responses of these two arrays. When the Monte Carlo simulation is performed for these two arrays, the average mismatch is 1.1% and 2.7%, respectively, showing that our array layouts are expected to have performance superior to those described in Kare. Review of Table 1 reveals that, as expected, lower Voronoi cell median aspect ratios are correlated with lower beam mismatches.

### Voltage Boost

In some cases, the nominal output voltage of PV cells would require an excessively large number to be connected in series to reach the desired array output voltage. In other cases, the current out of PV cells might be so high that ohmic losses would be unacceptably large (or the size of wiring required to extract current would be unacceptably large). In these cases, one or more PV cells in the same voltage level could have a DC/DC voltage boost circuit connected to the PV output, thereby increasing the voltage seen by the rest of the array and reducing the current that needs to be carried throughout the wiring.

There are a variety of DC/DC boost circuit topologies, with the performance depending on the requirement. Some regulate the input to a fixed, narrow voltage output, even if the input varies over some relatively wide voltage range. Another option is a variable boost with a fixed input voltage setpoint (e.g., set at the PV cell's Maximum Peak Power voltage), which adjusts the boost ratio to achieve that MPP. In this case, the output voltage ‘floats’ or is unregulated; instead, the load (e.g., a battery) controls the output voltage by sinking the current. MPP with dynamic input setpoint is MPPT (maximum power point tracking), where an algorithm dynamically adjusts the boost ratio to keep the PV device at peak power by, for example, measuring both current and power to calculate power. This peak power tracking may be based on power out of the PV device, or power out of the converter. Another boost circuit option is a so-called “fixed-ratio” circuit, that increases the input voltage by a fixed multiplicative ratio. Boost (and buck) DC/DC voltage converters will be familiar to those of ordinary skill in the art and are not further described herein. Details may be found in electronics texts such as Pressman et. al, Switching Power Supply Design, 3d ed., McGraw Hill, 2009, pp. 31-43, which is incorporated by reference herein to the extent not inconsistent herewith.

While any of the above-described types of boost circuits could be used with the distributed wiring arrangements described herein, use of fixed-ratio boost converters are particularly attractive to efficiently balance the PV cell and PV cell groups output currents while achieving the desired output voltage. In particular, when using a fixed-ratio type of boost circuit, the boosted output is expected to behave like an unboosted PV cell (for example, exhibiting a similar I-V curve shape), instead of like a fixed voltage device. Such a use of DC boost circuitry may enable other parts of an array's electronics to be “agnostic” about PV cell material, single-junction vs. multi-junction, or other characteristics of PV cells. In one specific example, a multi-junction InGaAs PV cell has a nominal output voltage of ˜5V, and a single-junction InGaAs PV cell has a nominal output voltage of ˜0.7V (both of these types of cells are designed for 976 nm light, although those of ordinary skill in the art will appreciate that the same principles apply to other wavelengths). A fixed-ratio boost of around ˜7× would enable the 0.7V PV cell to behave like a 5V cell as far as the rest of the array and connected electronics (e.g., PMAD hardware 308) are concerned. If voltage boost electronics providing a 7× boost are installed on a carrier 608 for the single-junction cells, it could be swapped for a carrier 608 carrying multi-junction cells (without voltage boost) without changing out other hardware. Of course, other combinations of light wavelengths, PV cell materials, and boost circuits are possible. This type of interoperability may have advantages for receiver design and manufacture.

### Dynamic Wiring

As mentioned above, in some implementations, waffle board 402 (or other similar components such as PV carrier 608) may allow a programmatic switching of wiring of PV cells 406, allowing the serial and parallel connections to be adjusted to suit PV cell selection, power beam parameters, environmental operating conditions, or to achieve other engineering goals that will occur to those of ordinary skill in the art. For example, it might be desirable to use a different number of voltage groups depending on the size and/or profile of an incoming power beam. In another example, wiring might be switched to a particular layout only once, when the array is first deployed, allowing the same array switching hardware to be used for multiple different power beaming installations having different required output voltages.

In some implementations, receiver 104 may include a processor configured to determine an optimal serial-parallel layout for an incoming beam (and, in some implementations, output load requirement) and to establish that wiring layout at the start of power beaming. For a sufficiently fast and versatile processor, receiver 104 might even be able to switch to an optimal layout “on the fly.” However, if it is not desirable to provide so much processing power for this task (for example, if the processor consumes more power than the savings achieved by use of the optimal layout), it may be preferable to provide a small (or large) “library” of PV cell wiring layouts, so that receiver 104 can choose from a list, rather than determining a layout ab initio. Such selection may be performed automatically by receiver 104, or it may be manually selected, for example using user interface 320.

In one example, a processor includes a library of three PV cell wiring layouts for a 10×10 array of cells, and receiver 104 includes suitable physical wiring to implement any of the three by the operation of switches or equivalent components. A first layout (which may be used as a default layout) includes five voltage groups arranged as shown in FIG. 15. A second layout may include ten voltage groups, arranged in a staggered pattern with an offset of 3. A third layout may use only the center 8×8 set of PV cells, grouping them into four voltage groups, arranged in a staggered pattern with an offset of 2 as shown in FIG. 11. During use of this example receiver, the processor may determine (or the user may select) that a higher output voltage is required and may respond by switching the wiring from the default first layout to the second layout.

Alternatively, the processor may determine (e.g., by communicating with a sensor detecting the output current at individual PV cells) that the incoming power beam is sufficiently tightly focused that the outermost PV cells are making only a negligible contribution to the output current and may respond by switching to the third layout. While these examples describe switching between different PV cell layouts on a relatively long time scale, in some implementations, this type of switching may occur rapidly and continuously, for example in response to scintillation of the power beam.

In some implementations, dynamic wiring configurations may be used to implement DC/DC voltage boost. DC/DC converters require power to operate, so in some implementations where multiple converters are provided, it may be useful for the processor to monitor currents and choose to shut down some converters if they are not saving more power than they are using. In an extreme case, receiver 104 might include a boost circuit for each PV cell, but when there is minimal optical flux, the entire PV array could feed one DC/DC converter. Of course, intermediate cases are also contemplated.

In the following, further features, characteristics, and advantages are described by items:

Item 1: A power receiver includes a plurality of photovoltaic (PV) cells disposed on a support surface and electrical wiring for interconnecting the PV cells. The PV cells are divided into a plurality of voltage groups, each voltage group having a selected output voltage and output current. The wiring is configured to connect each PV cell within a voltage group in parallel and to connect each voltage group to at least one other voltage group in series. The PV cells of each voltage group are arranged to be noncontiguous with one another on the support surface, and the plurality of voltage groups exhibits a current mismatch of less than 5% when the receiver is exposed to a power beam, where current mismatch is defined as the difference between the greatest output current and the least output current, divided by the average output current. This type of power receiver may provide a technical benefit of improving power conversion efficiency by reducing current mismatch.

Item 2: The power receiver of item 1, where the power beam is a laser power beam.

Item 3: The power receiver of item 1 or 2, where the power beam has a substantially Gaussian beam profile.

Item 4: The power receiver of any of items 1-3, where the power beam has a super-Gaussian beam profile.

Item 5: The power receiver of any of items 1-4, where the current mismatch is less than 4%.

Item 6: The power receiver of any of items 1-5, where the current mismatch is less than 3%.

Item 7: The power receiver of any of items 1-6, where the current mismatch is less than 2%.

Item 8: The power receiver of any of items 1-7, where the current mismatch is less than 1%.

Item 9: The power receiver of any of items 1-8, where the PV cells are arranged in a rectangular shape.

Item 10: The power receiver of any of items 1-9, where the PV cells are arranged in a square shape.

Item 11: The power receiver of any of items 1-10, where the PV cells are arranged in a square shape having truncated corners.

Item 12: The power receiver of any of items 1-11, where the PV array includes four voltage groups.

Item 13: The power receiver of any of items 1-12, where the PV array includes five voltage groups.

Item 14: The power receiver of any of items 1-13, where the PV array includes six voltage groups.

Item 15: A power receiver includes a plurality of photovoltaic (PV) cells disposed on a support surface and electrical wiring for interconnecting the PV cells. The PV cells are divided into a plurality of voltage groups, each voltage group having a selected output voltage and output current. The wiring is configured to connect each PV cell within a voltage group in parallel and to connect each voltage group to at least one other voltage group in series. The PV cells of each voltage group are arranged in a repeating pattern along a first axis of the PV array, the repeating pattern being staggered along a second axis of the PV array by an offset value. The offset value is selected so that PV cells in the same voltage group are not adjacent to one another. This type of power receiver may provide a technical benefit of improving power conversion efficiency by reducing current mismatch.

Item 16: The power receiver of item 15, where the PV cells are connected in series to one or more adjacent PV cells along the first axis, and where PV cells belonging to each voltage group are connected in parallel by means of additional wiring.

Item 17: The power receiver of item 15 or 16, where the additional wiring is located within the support surface.

Item 18: The power receiver of any of items 15-17, where the additional wiring is located behind the support surface.

Item 19: The power receiver of any of items 15-18, where the additional wiring is located in a circuit board having apertures placed to permit light to pass therethrough to reach the PV cells.

Item 20: The power receiver of any of items 15-19, where the PV cells are arranged to form a rectangular shape.

Item 21: The power receiver of any of items 15-20, where the PV cells are arranged to form a square shape.

Item 22: The power receiver of any of items 15-21, where the PV cells are arranged to form a square shape having truncated corners.

Item 23: The power receiver of any of items 15-22, where the PV array includes four voltage groups.

Item 24: The power receiver of any of items 15-23, where the PV array includes five voltage groups.

Item 25: The power receiver of any of items 15-24, where the PV array includes six voltage groups.

Item 26: A power receiver includes a plurality of photovoltaic (PV) cells disposed on a support surface and electrical wiring for interconnecting the PV cells. The PV cells are divided into a plurality of voltage groups, each voltage group having a selected output voltage and output current. The wiring is configured to connect each PV cell within a voltage group in parallel and to connect each voltage group to at least one other voltage group in series. Each voltage group has the property that a Voronoi mesh generated from positions of PV cells in the voltage group has a median Voronoi cell aspect ratio of less than 1.4. This type of power receiver may provide a technical benefit of improving power conversion efficiency by reducing current mismatch, by ensuring that PV cells in a voltage level are distributed evenly across the array surface.

Item 27: The power receiver of item 26, where each voltage group has the property that a Voronoi mesh generated from positions of PV cells in the voltage group has a median Voronoi cell aspect ratio of less than 1.3.

Item 28: A power receiver including a plurality of photovoltaic (PV) cells, a circuit board having a plurality of apertures therein, and an output connector. Each PV cell has an active surface configured to receive light for conversion to electric power, and a cathode connector and an anode connector configured to produce a voltage therebetween when the active surface of the PV cell is exposed to light. The circuit board is connected to at least one of the cathode and anode connectors, and the output connector is configured to electrically connect the circuit board to a load. Each PV cell of the plurality is positioned to receive light that has passed through at least one of the plurality of apertures in the circuit board. This type of power receiver may provide a technical benefit of using space efficiently for electronics to allow collection and conversion into energy of more light in a given area.

Item 29: The power receiver of item 28, further including a reflector associated with at least one PV cell of the plurality, where the reflector is configured to reflect light onto the active surface of the at least one associated PV cell.

Item 30: The power receiver of item 28 or 29, further including a plurality of reflectors, each reflector associated with at least one PV cell of the plurality, wherein each reflector is configured to reflect light onto the active surface of the at least one associated PV cell.

Item 31: The power receiver of any of items 28-30, where at least some members of the plurality of reflectors are positioned within the apertures of the circuit board.

Item 32: The power receiver of any of items 28-31, where the circuit board includes wiring configured to connect a first subset of the PV cells in parallel.

Item 33: The power receiver of any of items 28-32, where the wiring configured to connect the first subset of the PV cells in parallel is positioned on a first layer of the circuit board.

Item 34: The power receiver of any of items 28-33, where the circuit board includes wiring configured to connect a second subset of the PV cells in parallel, the second subset and the first subset having no PV cells in common.

Item 35: The power receiver of any of items 28-34, where the wiring configured to connect the first subset of the PV cells in parallel is positioned on a first layer of the circuit board, and the wiring configured to connect the second subset of the PV cells in parallel is positioned on a second layer of the circuit board differing from the first layer.

Item 36: The power receiver of any of items 28-35, where the circuit board further includes wiring configured to connect the first subset to the second subset in series, thereby producing a voltage approximately equal to a sum of a first voltage between a cathode connector and an anode connector of a PV cell of the first subset and a second voltage between a cathode connector and an anode connector of a PV cell of the second subset.

Item 37: The power receiver of any of items 28-36, where all electrical connections between different PV cells of the plurality include wiring in the circuit board.

Item 38: The power receiver of any of items 28-37, where the circuit board is configured to dynamically change connections between different PV cells.

Item 39: The power receiver of any of items 28-38, further including a heat sink configured to remove waste heat from the PV cells.

Item 40: The power receiver of any of items 28-39, where the heat sink has a surface that acts as a reference surface for positioning optical components of the power receiver.

Item 41: A power receiver includes a heat sink including a first side, a second side, and an opening passing from the first side to the second side, a power collection device in thermal contact with the first side of the heat sink, an electronic component disposed on the second side of the heat sink, and an electrical connector arranged within the opening in the heat sink. The electrical connector connects the power collection device to the electronic component. This type of power receiver may provide a technical benefit of allowing more space for electronics without blocking light or requiring additional space between cells, which may allow collection and conversion into energy of more light in a given area. Further technical benefit may be achieved by the placement of the heat sink (or a thermal connection thereto) closer to the location where waste heat is generated, allowing power collection devices to operate closer to their preferred temperatures even in the presence of high-energy power beams.

Item 42: The power receiver of item 41, where the heat sink is fabricated from a thermally conductive material.

Item 43: The power receiver of item 41 or 42, where the thermally conductive material is a metal or a ceramic.

Item 44: The power receiver of any of items 41-43, where the power collection device is a photovoltaic (PV) cell.

Item 45: The power receiver of any of items 41-44, where the heat sink includes internal channels configured for circulation of a cooling fluid.

Item 46: The power receiver of any of items 41-45, where the heat sink includes a vapor chamber.

Item 47: The power receiver of any of items 41-46, where the heat sink includes a plurality of openings passing from the first side to the second side, the power receiver further including a plurality of electrical connectors arranged with the openings in the heat sink.

Item 48: The power receiver of any of items 41-47, further including a plurality of power collection devices mounted on the first side of the heat sink, wherein the plurality of electrical connectors connect each one of the plurality of power collection devices to the electronic component mounted on the second side of the heat sink.

While the foregoing has described what are considered to the best mode and/or other examples, it is understood that various modifications may be made therein, and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow.

That scope is intended to be as broad as is consistent with the ordinary meanings of the language that is used in the claims when interpreted in light of this specification and the prosecution history that follows and to encompass all structural and functional equivalents. Notwithstanding, none of the claims are intended to embrace subject matter that fails to satisfy the requirements of Sections 101, 102, or 103 of the Patent Act, nor should they be interpreted in such a way. Any unintended embracement of such subject matter is hereby disclaimed.

Except as stated in the previous paragraph, nothing that has been stated or illustrated is intended or should be interpreted to cause a dedication of any component, step, feature, objects, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity from another without necessarily implying any relationship or order between such entities. The terms “comprise” and “include” in all their grammatical forms are intended to cover a non-exclusive inclusion, so that a process, method, article, apparatus, or composition of matter that comprises or includes a list of elements may also include other elements not expressly listed. An element preceded by “a” or “an” does not, without further constraints, preclude the existence of additional identical or similar elements.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features may be grouped together in various examples for the purpose of clarity of explanation. This method of disclosure is not to be interpreted as reflecting an intention that the claims require more features than are expressly recited in each claim. Furthermore, features from one example may be freely included in another, or substituted for one another, without departing from the overall scope and spirit of the instant application.

1. A power receiver, comprising:
a plurality of photovoltaic (PV) cells disposed on a support surface, the PV cells divided into a plurality of voltage groups, each voltage group having a selected output voltage and output current; and
electrical wiring for interconnecting the PV cells, the wiring configured to:
connect each PV cell within a voltage group in parallel; and
connect each voltage group to at least one other voltage group in series,
wherein:
the PV cells of each voltage group are arranged to be not adjacent to one another on the support surface; and
the plurality of voltage groups exhibits a current mismatch of less than 5%, where current mismatch is defined as the difference between the greatest output current and the least output current, divided by the average output current, when the receiver is exposed to a power beam.

2. The power receiver of claim 1, wherein the power beam is a laser power beam.

3. The power receiver of claim 1, wherein the power beam has a substantially Gaussian beam profile.

4. The power receiver of claim 1, wherein the power beam has a super-Gaussian beam profile.

5. The power receiver of claim 1, wherein the current mismatch is between 3% and 4%.

6. The power receiver of claim 1, wherein the current mismatch is between 2% and 3%.

7. The power receiver of claim 1, wherein the current mismatch is between 1% and 2%.

8. The power receiver of claim 1, wherein the current mismatch is less than 1%.

9.-11. (canceled)

12. The power receiver of claim 1, wherein the PV array includes four voltage groups.

13-14. (canceled)

15. A power receiver, comprising:
a plurality of photovoltaic (PV) cells disposed on a support surface to form a PV array, the PV cells divided into a plurality of voltage groups; and
electrical wiring for interconnecting the PV cells, the wiring configured to:
connect each PV cell within a voltage group in parallel; and
connect each voltage group to at least one other voltage group in series,
wherein:
the PV cells of each voltage group are arranged in a repeating pattern along a first axis of the PV array, and where the repeating pattern is staggered along a second axis of the PV array by an offset value, the offset value selected so that PV cells in the same voltage group are not adjacent to one another.

16. The power receiver of claim 13, wherein the PV cells are connected in series to one or more adjacent PV cells along the first axis, and wherein PV cells belonging to each voltage group are connected in parallel by means of additional wiring.

17. The power receiver of claim 16, wherein the additional wiring is located within the support surface.

18. The power receiver of claim 16, wherein the additional wiring is located behind the support surface.

19. The power receiver of claim 16, wherein the additional wiring is located in a circuit board having apertures placed to permit light to pass therethrough to reach the PV cells.

20.-22. (canceled)

23. The power receiver of claim 13, wherein the PV array includes four voltage groups.

24.-25. (canceled)

26. A power receiver, comprising:
a plurality of photovoltaic (PV) cells disposed on a support surface to form a PV array, the PV cells divided into a plurality of voltage groups; and
electrical wiring for interconnecting the PV cells, the wiring configured to:
connect each PV cell within a voltage group in parallel; and
connect each voltage group to at least one other voltage group in series,
wherein each voltage group has the property that a Voronoi mesh generated from positions of PV cells in the voltage group has a median Voronoi cell aspect ratio of less than 1.4.

27. The power receiver of claim 24, wherein each voltage group has the property that a Voronoi mesh generated from positions of PV cells in the voltage group has a median Voronoi cell aspect ratio of less than 1.3.

28. A power receiver, comprising:
a plurality of photovoltaic (PV) cells, each PV cell having:
an active surface configured to receive light for conversion to electric power; and
a cathode connector and an anode connector configured to produce a voltage therebetween when the active surface of the PV cell is exposed to light;
a circuit board connected to at least one of the cathode and anode connectors, the circuit board having a plurality of apertures therein; and
an output connector configured to electrically connect the circuit board to a load,
wherein each PV cell is positioned to receive light that has passed through at least one of the plurality of apertures in the circuit board.

29.-31. (canceled)

32. The power receiver of claim 28, wherein the circuit board includes wiring configured to connect a first subset of the PV cells in parallel.

33.-40. (canceled)

41. A power receiver, comprising:
a heat sink including a first side, a second side, and an opening passing from the first side to the second side;
a power collection device in thermal contact with the first side of the heat sink;
an electronic component disposed on the second side of the heat sink; and
an electrical connector arranged within the opening in the heat sink, wherein the electrical connector connects the power collection device to the electronic component.

42.-48. (canceled)

49. The power receiver of claim 1, wherein the current mismatch is between 4% and 5%.
